(19) United States
(12) Patent Application Publication
(10) Pub. No.: US 2025/0221093 A1
(43) Pub. Date: Jul. 3, 2025

(54) Display Device and Method for Manufacturing Display Device

(71) Applicant: LG Display Co., Ltd., Seoul (KR)

(72) Inventors: Chunghwan An, Goyang-si (KR); Eunjeong Shin, Paju-si (KR); Jongha Jae, Uiwang-si (KR)

(21) Appl. No.: 18/824,895

(22) Filed: Sep. 4, 2024

(30) Foreign Application Priority Data
Jan. 3, 2024 (KR) 10-2024-0001201

(51) Int. Cl. H01L 33/00; B23K 26/06; B23K 26/082; H01L 25/075

(52) U.S. Cl. CPC H10H 20/01; B23K 26/0661; B23K 26/082; H01L 25/0753

(57) ABSTRACT

The disclosure relates to a display device and a method for manufacturing the display device. A display device includes a display panel including a plurality of light-emitting areas and a plurality of non-light-emitting areas arranged alternately with each other in a row direction and/or a column direction; a plurality of light-emitting elements disposed in the light-emitting areas of the display panel and arranged in a plurality of rows and a plurality of columns; and a plurality of micro keys disposed in the non-light-emitting area between the light-emitting areas adjacent to each other in the row direction and/or the column direction.

### CROSS-REFERENCE TO RELATED APPLICATION

This application claims priority to Republic of Korea Patent Application No. 10-2024-0001201 filed on Jan. 3, 2024, which is hereby incorporated by reference in its entirety.

### BACKGROUND

### Technical Field

The present disclosure relates to a display device and a method for manufacturing the display device. More specifically, the present disclosure relates to a display device including an LED (light-emitting diode) and a method for manufacturing the display device.

### Related Art

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with a built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of an inorganic material that is resistant to moisture and oxygen and thus is not affected by the external environment and thus has high reliability and has a long lifespan compared to the organic light-emitting display device.

### SUMMARY

A purpose of the present disclosure is to provide a display device and a method for manufacturing the display device in which a transfer process of transferring light-emitting elements from a wafer to a donor substrate may be simplified to improve a production amount of the light-emitting elements.

Another purpose of the present disclosure to provide a display device and a method for manufacturing the display device in which both the light-emitting elements and micro keys may be transferred to the donor substrate using a single laser mask, and thus, the accuracy of the position to which the light-emitting element is transferred to the donor substrate and thus the transfer precision may be improved. Furthermore, mask patterns designed based on various pitches may be applied to a single laser mask, thereby diversifying a mask model and thus improving the lifespan of the laser mask.

Still another purpose of the present disclosure is to provide a display device and a method for manufacturing the display device in which the laser beam travels until one mask pattern of a plurality of mask patterns constituting the laser mask and one of a plurality of island patterns of the micro key overlaps each other, thereby preventing the micro key from being damaged by the laser beam or at least reducing the risk of damage from the laser beam.

One embodiment of the present disclosure provides a display device comprising: a display panel including a plurality of light-emitting areas and a plurality of non-light-emitting areas arranged alternately with each other in a row direction and/or a column direction; a plurality of light-emitting elements disposed in the light-emitting areas of the display panel and arranged in a plurality of rows and a plurality of columns; and a plurality of micro keys disposed in the non-light-emitting area between the light-emitting areas adjacent to each other in the row direction and/or the column direction.

Another embodiment of the present disclosure provides a method for manufacturing a display device, the method comprising: a first transfer step of transferring a plurality of light-emitting elements, a plurality of macro keys, and a plurality of micro keys disposed on the wafer onto a donor substrate; providing a display panel including a plurality of light-emitting areas and a plurality of non-light-emitting areas arranged alternately with each other in a row direction and/or a column direction; and a second transfer step of transferring the plurality of light-emitting elements and the plurality of micro keys from the donor substrate to the display panel, wherein the plurality of micro keys are transferred to the non-light-emitting area between the light-emitting elements adjacent to each other.

Another embodiment of the present disclosure provides a method for manufacturing a display device, the method comprising: providing a first donor substrate including a plurality of light-emitting elements emitting a first color of light, a second donor substrate including a plurality of light-emitting elements emitting a second color of light, and a third donor substrate including a plurality of light-emitting elements emitting a third color of light, wherein each of the first donor substrate, the second donor substrate, and the third donor substrate respectively comprises micro keys arranged in the side regions of the corresponding plurality of light-emitting elements; and transferring the plurality of light-emitting elements and the micro keys on the first donor substrate, the second donor substrate, and the third donor substrate to each of a plurality of set areas of a display panel, such that light-emitting elements emitting different colors of light in each set area are arranged in parallel in a row direction, wherein the display panel comprises a plurality of light-emitting areas and a plurality of non-light-emitting areas arranged alternately with each other in the row direction and/or a column direction, and wherein adjacent ones in the plurality of set areas overlap with each other, and the micro keys in the overlapping region are located in the non-light-emitting area between the light-emitting elements adjacent to each other.

According to embodiments of the present disclosure, the number of times the laser beam scans the wafer when transferring the plurality of light-emitting elements to the donor substrate may be reduced such that the transfer process may be simplified, and thus, the production amount of the light-emitting elements may be increased within the same process operating time. Production energy may be reduced via this process optimization.

According to embodiments of the present disclosure, both the light-emitting elements and the micro keys may be transferred to the donor substrate using a single laser mask, and thus, the accuracy of the position to which the light-emitting element is transferred to the donor substrate and thus the transfer precision may be improved. Furthermore, mask patterns designed based on various pitches may be applied to a single laser mask, thereby diversifying a mask model and thus improving the lifespan of the laser mask.

According to embodiments of the present disclosure, the laser beam travels until one mask pattern of a plurality of mask patterns constituting the laser mask and one of a plurality of island patterns of the micro key overlaps each other, thereby preventing the micro key from being damaged by the laser beam or at least reducing the risk of damage from the laser beam.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF DRAWINGS

FIG. 1 is a plan view of a wafer on which a plurality of light-emitting elements are arranged according to an embodiment of the present disclosure.

FIG. 2 is a cross-sectional view cut along a cutting line 2-2 in FIG. 1 according to an embodiment of the present disclosure.

FIG. 3 is a plan view of a donor substrate before a plurality of light-emitting elements are transferred thereto according to an embodiment of the present disclosure.

FIG. 4 is a schematic diagram for illustrating a process of transferring a plurality of light-emitting elements disposed on a wafer to a donor substrate according to an embodiment of the present disclosure.

FIGS. 5A and 5B are diagrams for illustrating a laser mask and a micro key mask according to an embodiment of the present disclosure.

FIGS. 6, 7, 8, 9, 10, 11A, 11B, 12, 13, 14, 15, and 16 are diagrams for illustrating a display device and a method for manufacturing the display device according to another embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to inform the scope of the present disclosure to those of ordinary skill in the technical field.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting to the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or period from another element, component, region, layer or period. Thus, a first element, component, region, layer or period as described under could be termed a second element, component, region, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

Hereinafter, a display device according to each embodiment of the present disclosure is described with reference to the attached drawings.

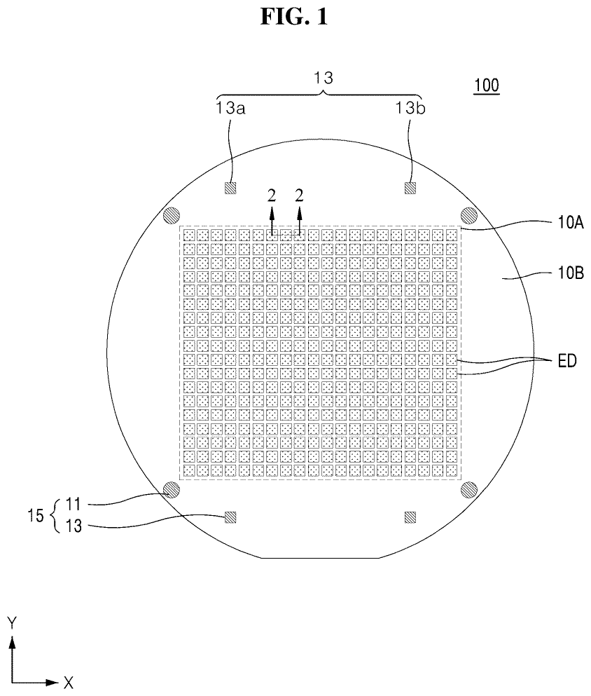

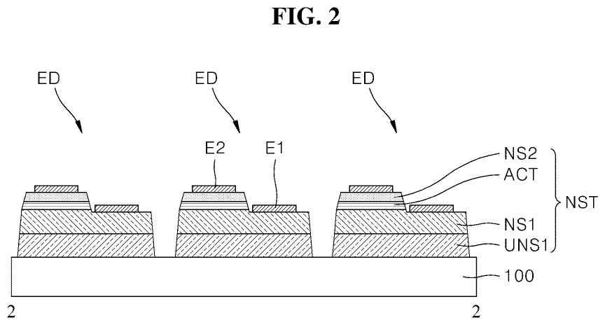

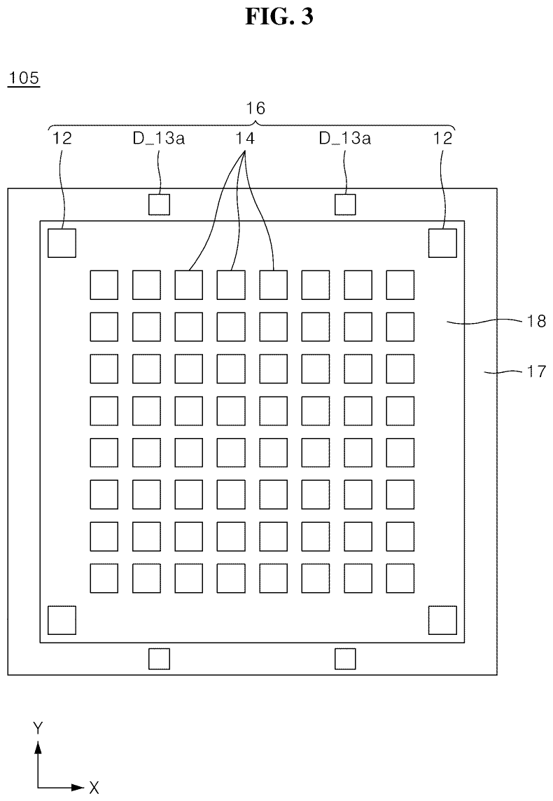

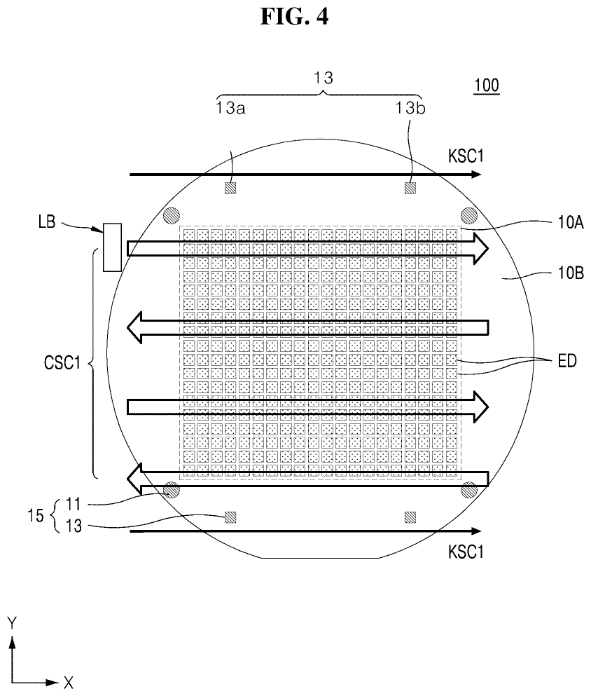

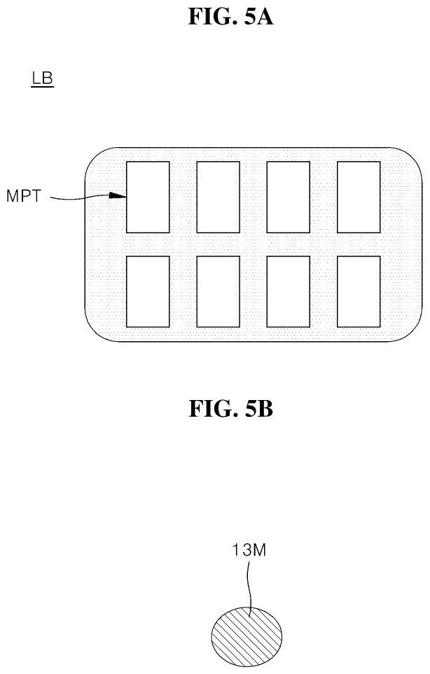

FIGS. 1 to 5B are diagrams for illustrating a display device and a method for manufacturing the display device according to an embodiment of the present disclosure. Specifically, FIG. 1 is a plan view of a wafer on which a plurality of light-emitting elements are arranged according to an embodiment of the present disclosure. FIG. 2 is a cross-sectional view cut along a cutting line 2-2 in FIG. 1. FIG. 3 is a plan view of the donor substrate before the plurality of light-emitting elements are transferred thereto. FIG. 4 is a schematic diagram for illustrating a process of transferring the plurality of light-emitting elements disposed on a wafer to the donor substrate. FIGS. 5A and 5B are diagrams illustrating a laser mask and a micro key mask.

Referring to FIGS. 1 to 5B, a plurality of light-emitting elements ED is formed on a wafer 100. The wafer 100 may be made of a material such as sapphire, silicon (Si), silicon carbide (SiC), or gallium arsenide (GaAs). However, embodiments of the present disclosure are not limited thereto.

The light-emitting element ED may be formed on the wafer 100 using an epitaxial growth scheme. For example, an undoped semiconductor layer UNS1, a first semiconductor layer NS1, an active layer ACT, and a second semiconductor layer NS2 are sequentially grown on the wafer 100 to form a nitride semiconductor structure NST. The nitride semiconductor structure NST is cut into individual light-emitting element chips. Then, a first electrode E1 is disposed on the first semiconductor layer NS1 and a second electrode E2 is disposed on the second semiconductor layer NS2. Thus, the light-emitting element ED may be formed. Each of the first semiconductor layer NS1 and the second semiconductor layer NS2 may be made of a nitride semiconductor. For example, each of the first semiconductor layer NS1 and the second semiconductor layer NS2 may be made of a GaN-based semiconductor material.

Specifically, each of the first semiconductor layer NS1 and the second semiconductor layer NS2 may be a layer made of a material such as gallium nitride (GaN), indium aluminum phosphide (InAIP), or gallium arsenide (GaAs) doped with an n-type or p-type impurity. The p-type impurity may be magnesium (Mg), zinc (Zn), beryllium (Be), etc., and the n-type impurity may be silicon (Si), germanium, tin (Sn), etc. However, embodiments of the present disclosure are not limited thereto.

The active layer ACT may have a single-layer or multi-quantum well (MQW) structure, and may include, for example, a nitride-based semiconductor material such as indium gallium nitride (InGaN) or gallium nitride (GaN). The active layer ACT may be located on one side of an upper surface of the first semiconductor layer NS1, and the second semiconductor layer NS2 may be located on the active layer ACT.

The first electrode E1 may be disposed on an exposed portion of the upper surface of the first semiconductor layer NS1 on which the active layer ACT is not disposed. The second electrode E2 may be disposed on the second semiconductor layer NS2.

Each of the plurality of light-emitting elements ED is an element that may emit light on its own. Each of the plurality of light-emitting elements ED may emit red light, green light, or blue light. On one wafer 100, the plurality of light-emitting elements that emit light of the same color may be formed.

Each of the plurality of light-emitting elements ED may be an LED (Light-Emitting Diode) or micro-LED. However, embodiments of the present disclosure are not limited thereto. An example of the present disclosure in which the light-emitting element ED has a horizontal structure as shown in FIG. 2 is described. However, embodiments of the present disclosure are not limited thereto. For example, each of the plurality of light-emitting elements ED may include a vertical structure or a flip chip structure.

The plurality of light-emitting elements ED formed on the wafer 100 are transferred from the wafer 100 to a donor substrate 105 in FIG. 3 in a first transfer process, and are transferred from the donor substrate 105 to a display panel in a second transfer process. In other words, the plurality of light-emitting elements ED are transferred from the wafer 100 to the donor substrate 105 and then are transferred from the donor substrate 105 to the display panel PN. Thus, a manufacturing process of the display device may be completed.

The first transfer process is a process of transferring the plurality of light-emitting elements ED from the wafer 100 to the donor substrate 105.

The wafer 100 may include an active area 10A and a peripheral area 10B surrounding the active area 10A. The active area 10A is the area where the plurality of light-emitting elements ED are formed, and the peripheral area 10B is an area where a plurality of alignment keys 15 are disposed.

The plurality of light-emitting elements ED may be arranged in a matrix manner in a first direction (an X-axis direction) and a second direction (a Y-axis direction) in the active area 10A. The active area 10A may have a rectangular area due to the arrangement of the plurality of light-emitting elements ED in the matrix shape. However, embodiments of the present disclosure are not limited thereto. When the active area 10A includes the rectangular area, the active area may include both opposing sides in a column direction and both opposing sides in a row direction.

The plurality of alignment keys 15 may include a macro key 11 and a micro key 13. The macro key 11 may be disposed on a position of the peripheral area 10B adjacent to each of four corners of the active area 10A. A plurality of macro keys 11 may be arranged for alignment accuracy. For example, the macro key 11 may be disposed on a position of the peripheral area 10B adjacent to each of both opposing corners in the row direction of the active area 10A in each of both opposing portions in the column direction of the peripheral area 10B of the wafer 100.

The macro key 11 may be used to align the wafer 100 and the donor substrate 105 to each other. The micro key 13 may be used to align the donor substrate 105 and the display panel with each other. The two micro keys 13 may be disposed on each of the two opposing portions in the column direction (Y-direction) of the peripheral area 10B. The two micro keys 13 may be respectively disposed on both opposing positions in the row direction (X-direction) of each of the opposing portions in the column direction of the peripheral area 10B. The plurality of micro keys 13 may be disposed for alignment accuracy. For example, the micro key 13 may include a first micro key 13a and a second micro key 13b respectively disposed on both opposing positions in the row direction (X-direction) of each of the two opposing portions in the column direction (Y-direction) of the peripheral area 10B. The first micro key 13a and the second micro key 13b may be spaced from each other by a predefined spacing in the row direction (X-direction).

The micro key 13 may be transferred to the donor substrate 105 when the plurality of light-emitting elements ED formed on the wafer 100 is transferred to the donor substrate 105. The macro key 11 and the micro key 13 may be formed on the wafer 100 in a process of forming the plurality of light-emitting elements ED on the wafer 100. When the macro key 11 and the micro key 13 together with the plurality of light-emitting elements ED are formed on the wafer, each of the macro key 11 and the micro key 13 may include the same materials as at least some of the materials constituting the light-emitting element ED. In another example, the macro key 11 and the micro key 13 may be formed in a separate process from a process of forming the light-emitting element ED.

The macro key 11 and the micro key 13 may be formed to have different shapes and sizes. For example, the macro key 11 may have a circular shape, and the micro key 13 may have a rectangular shape. However, embodiments of the present disclosure are not limited thereto. Furthermore, the macro key 11 may have a relatively larger size than that of the micro key 13.

Referring to FIG. 3, the donor substrate 105 may include a base substrate 17, an adhesive layer 18, and a plurality of posts 16. The base substrate 17 supports the adhesive layer 18 and the plurality of posts 16 thereon, and may be made of a hard material. The adhesive layer 18 disposed on the base substrate 17 may fix the plurality of light-emitting elements ED transferred from the wafer 100 to the donor substate 105 to the donor substrate 105. The adhesive layer 18 may be made of, for example, a material having elasticity such as polydimethylsiloxane (PDMS), epoxy resin, or acrylic resin. However, embodiments of the present disclosure are not limited thereto.

The plurality of posts 16 may include a first post 14, a second post 12, and a third post D_13a. Some of the plurality of posts 16 (e.g., the first post 14 and the second post 12) may have a shape that protrudes from the adhesive layer 18 and may be made of the same material as that of the adhesive layer 18. In one example, some of the plurality of posts 16 (e.g. the first post 14 and the second post 12) may be integrated with the adhesive layer 18.

The first post 14 may include a plurality of posts disposed on an inner area of the adhesive layer 18 and arranged in a matrix manner in the X-axis direction as the first direction and the Y-axis direction as the second direction. Each of the plurality of light-emitting elements ED to be transferred to the display panel may be transferred to each of the plurality of first posts 14. In one example, each light-emitting element ED may be positioned in a corresponding manner to each first post 14.

The second post 12 may include a plurality of second posts 12 respectively disposed on corners of the adhesive layer 18. Each of the plurality of second posts 12 may be aligned with each of the macro keys 11 of the wafer 100 (see FIG. 1).

The third post D_13a may include a plurality of third posts D_13a which may be disposed on both opposing portions in the column direction (Y-direction) of the base substrate 17. The two third posts D_13a may be respectively disposed on both opposing positions in the row direction (X-direction) of each of the opposing portions in the column direction of the base substrate 17. That is, each of the plurality of third posts D_13a may be aligned with each of the micro keys 13 of the wafer 100 (see FIG. 1). Each of the micro keys 13 of the wafer 100 may be transferred to each of the plurality of third posts D_13a.

Referring to FIG. 4 along with FIG. 3, after the alignment of the wafer 100 and the donor substrate 105 with each other has been completed, a first transfer process is performed to transfer the plurality of light-emitting elements ED on the wafer 100 to the donor substrate 105. FIG. 4 shows only the wafer 100 for convenience of illustration.

The first transfer process may be performed using an LLO (Laser lift off) scheme. Specifically, in a state in which the wafer 100 and the donor substrate 105 (see FIG. 3) are positioned to face each other, a laser beam is irradiated to the plurality of light-emitting elements ED to be transferred to the donor substrate 105. The plurality of light-emitting elements ED to which the laser beam has been irradiated may be detached from the wafer 100 and then respectively adhered to the plurality of first posts 14 of the donor substrate 105.

In this regard, the plurality of micro keys 13a and 13b of the wafer 100 together with the light-emitting elements ED may be transferred to the donor substrate 105. For this purpose, a laser beam is irradiated onto the plurality of micro keys 13a and 13b to be transferred to the donor substrate 105. The plurality of micro keys 13a and 13b to which the laser beam has been irradiated may be detached from the wafer 100 and respectively adhered to the plurality of third posts D_13a of the donor substrate 105.

In one example, in the first transfer scheme using the laser lift-off scheme, the number of times the laser beam scans the wafer may affect a throughput of the light-emitting elements. For example, as the number of times the laser beam scans the wafer increases, a time taken to lift off the light-emitting element increases, resulting in a decrease in a time for which process equipment may operate, and thus resulting in a decrease in a production amount of the light-emitting elements. The number of times the laser beam scans the wafer may be affected by a length of the laser beam.

Referring again to FIG. 4, in the first transfer scheme using the laser lift-off scheme, the laser beam LB scans the wafer 100. Specifically, one side end of the wafer 100 in a first row may be a first scan start point, and the other side end opposite thereto of the wafer in the first row may be a first scan end point. In the scheme in which the laser beam LB scans the wafer, the laser beam LB may travel from the first scan start point in the X-axis direction as the first direction, and may reach the first scan end point. This is a first scan.

Next, the laser beam LB travels by a predetermined distance in the Y-axis direction as the second direction and reaches a second scan start point in a second row and travels therefrom in the first direction and reaches a second scan end point in the second row. This is a second scan. In other words, the laser scan may be performed in a manner such that the laser beam LB is irradiated to the wafer while traveling from the scan start point to the scan end point and then returns to the scan start point in a subsequent row.

In the scheme of transferring the plurality of micro keys 13a and 13b of the wafer 100 together with the light-emitting elements ED to the donor substrate 105, the active area 10A where the light-emitting elements ED are disposed and the peripheral area 10B where the micro keys 13a and 13b are disposed may be transferred to the donor substate 105 in a separate manner. Accordingly, the number of times the laser beam LB scans the wafer 100 increases. For example, a cycle CSC1 for which the laser beam LB scans the wafer 100 in the active area 10A may include four times of scans. As the peripheral area 10B where the micro keys 13a and 13b are disposed is separately transferred, the number of times the laser beam LB scans the peripheral area 10B may be two (two KSCIs). Accordingly, the first transfer scheme using the laser lift-off scheme requires at least 6 times the number of times the laser beam LB scans the wafer 100.

Referring to FIGS. 4 and 5A-5B, first laser masks MPT in FIG. 5A arranged in a pattern manner to which the laser beam LB is irradiated are used separately in order to simultaneously transfer the plurality of light-emitting elements ED from the wafer 100 onto the donor substrate 105. Further, a second laser mask 13M in FIG. 5B is used separately to transfer the micro key 13 to the donor substrate.

In the first transfer process, the laser beam LB separately scans the active area 10A where the light-emitting elements ED are disposed and the peripheral area 10B where the micro keys 13a and 13b are disposed. First, using the first laser masks MPT, the laser beam LB scans the active area 10A to detach the light-emitting elements ED from the wafer 100 and then the light-emitting elements ED are transferred to the donor substrate 105. Next, the first laser mask MPT is replaced with the second laser mask 13M, and then a further transfer process is performed on the peripheral area 10B to transfer the micro key 13 to the donor substrate 105. Therefore, it takes additional time to replace the first laser mask MPT with the second laser mask 13M. Further, as the first transfer process is repeated, a tolerance occurs in transfer position accuracy and transfer precision. For example, when using the two types of laser masks such as the first laser mask MPT and the second laser mask 13M, a position may be displaced due to the replacement process of the first laser mask MPT with the second laser mask 13M during the laser lift-off process, thereby causing the accuracy of the position to which the light-emitting element ED has been transferred and thus the transfer precision to be lowered.

In addition, even when multi-patterns of various shapes are introduced so that one laser mask may support multiple models, there may be a limitation in the number of models that may be introduced to the laser mask.

Accordingly, a method is needed to transfer the plurality of light-emitting elements ED and the micro key 13 to the donor substrate 105 while reducing the number of times the laser beam scans the wafer. Hereinafter, a description thereof will be made with reference to the drawings.

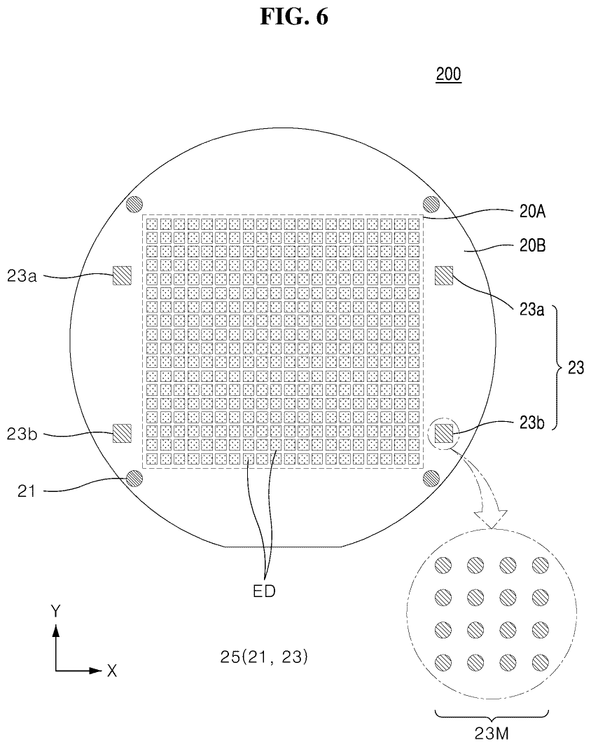

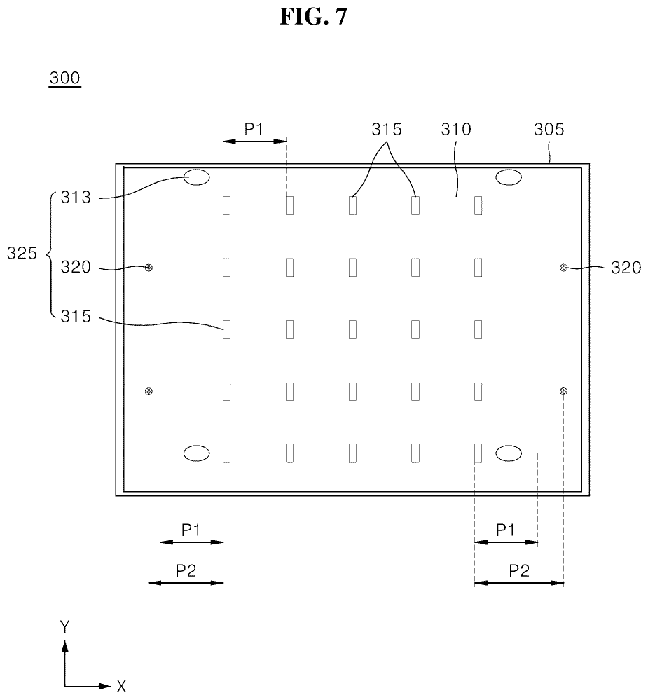

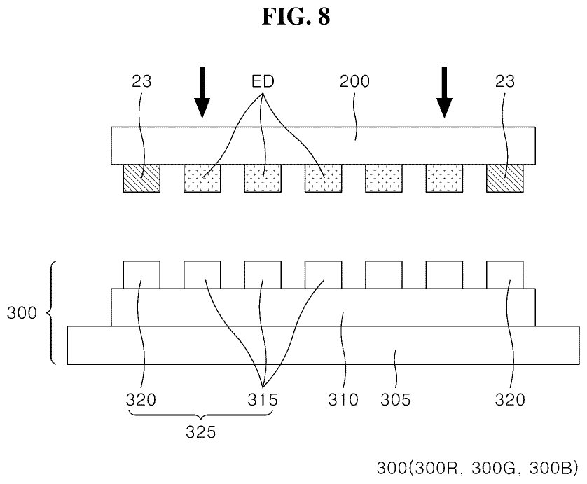

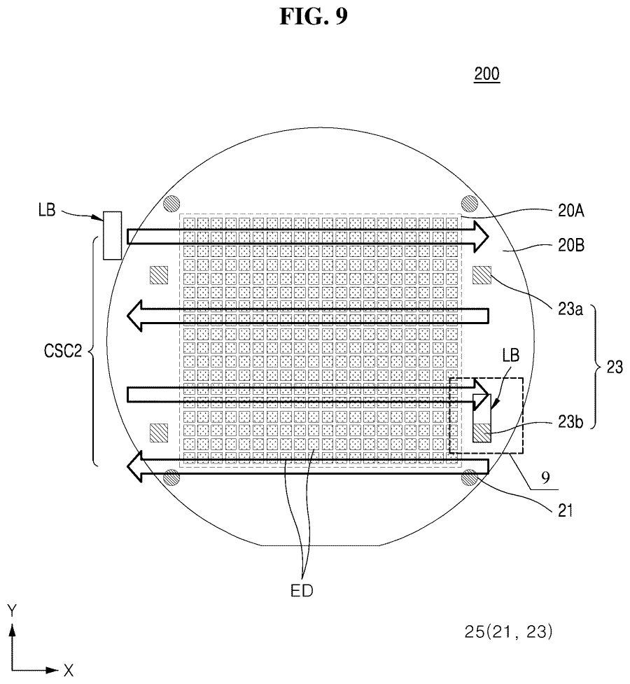

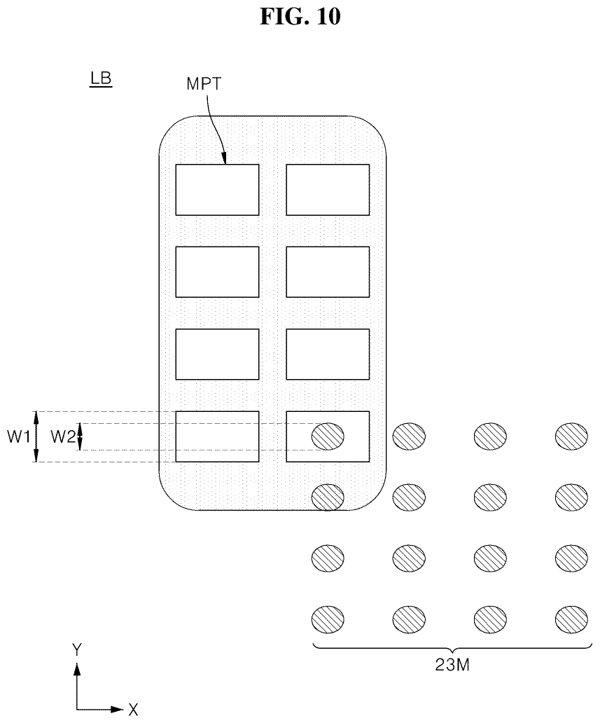

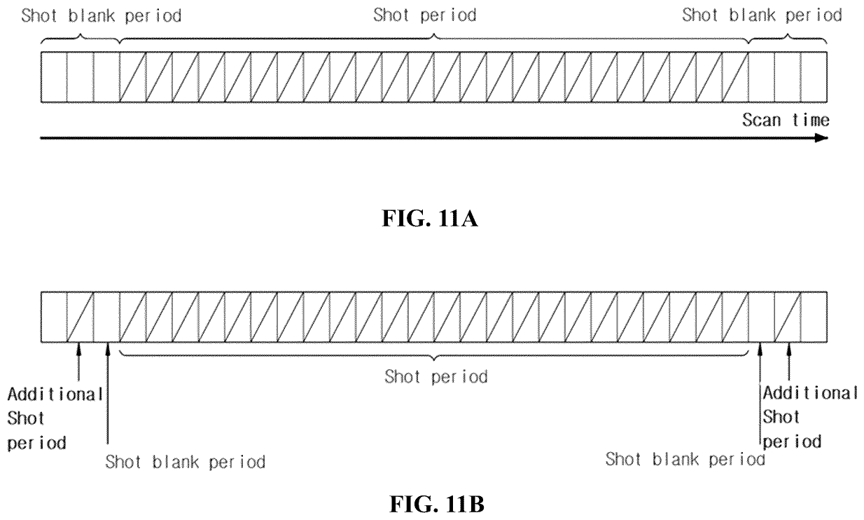

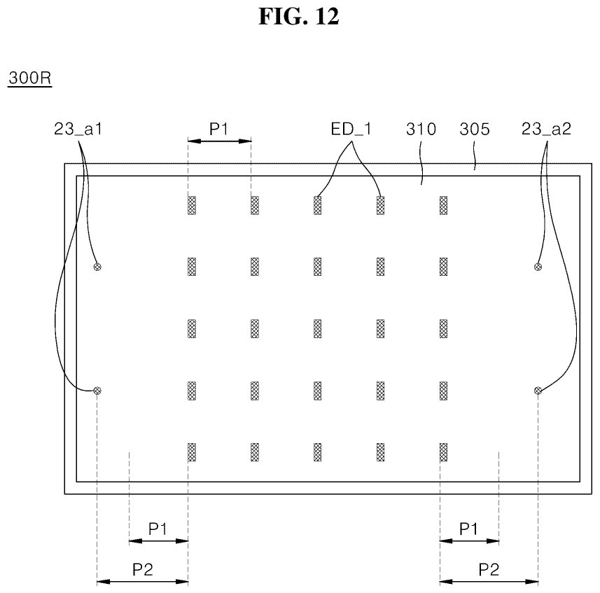

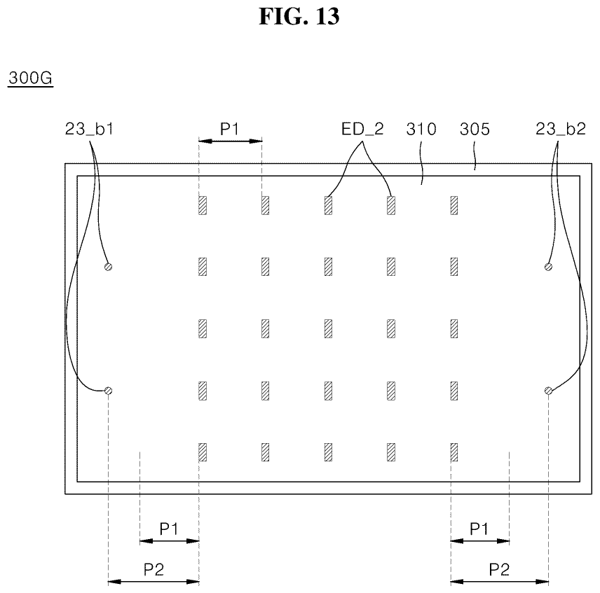

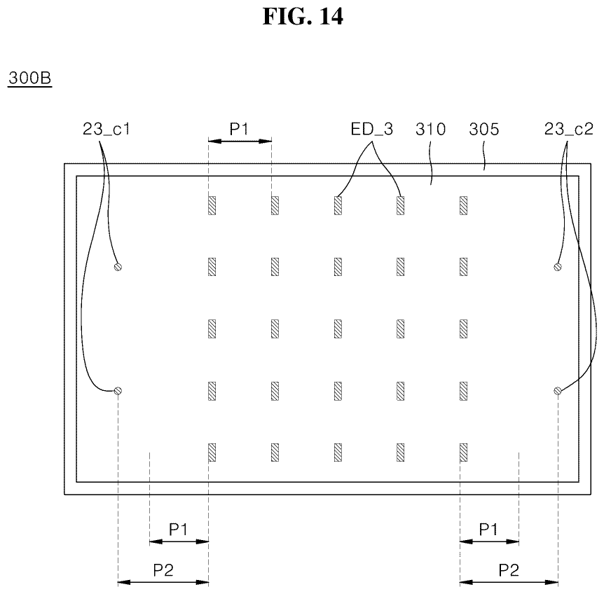

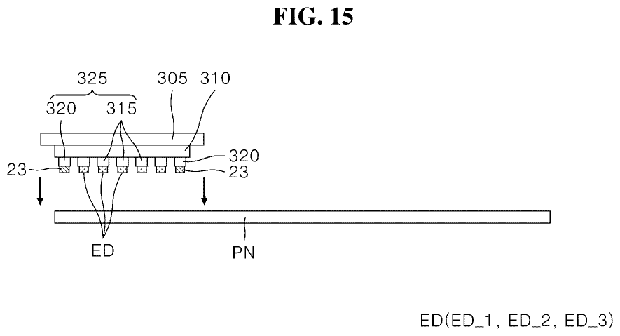

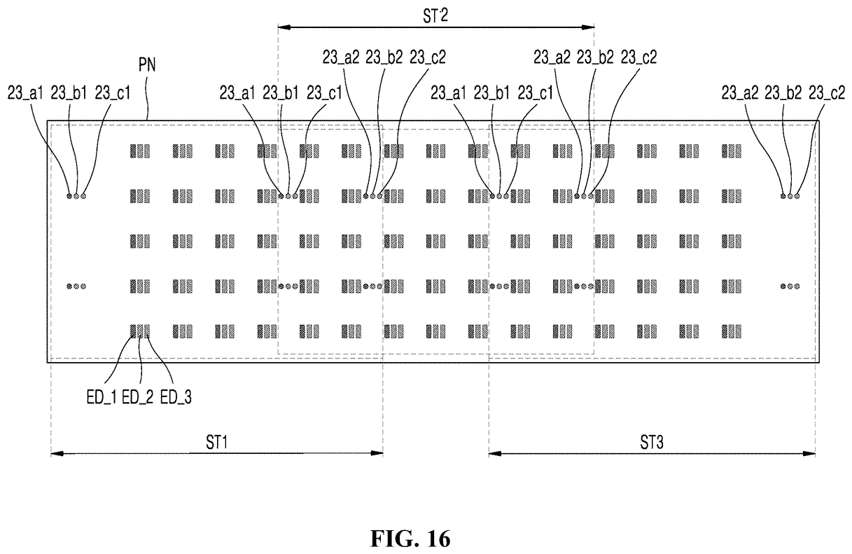

FIG. 6 to FIG. 16 are diagrams illustrating a display device and a method for manufacturing the display device according to another embodiment of the present disclosure in accordance with some embodiments of the present disclosure. Specifically, FIG. 6 is a plan view of a wafer on which a plurality of light-emitting elements are arranged according to another embodiment of the present disclosure. FIG. 7 is a plan view of the donor substrate before the plurality of light-emitting elements are transferred thereto according to another embodiment of the present disclosure. FIG. 8 and FIG. 9 are schematic diagrams illustrating the process of transferring the plurality of light-emitting elements disposed on the wafer to the donor substrate in accordance with some embodiments of the present disclosure. FIG. 10 is an enlarged plan view showing an area 9 of FIG. 9. FIGS. 11A and 11B are timing diagrams showing operations in which a laser beam scans the wafer according to the laser lift-off scheme. FIG. 12 is a plan view showing a first donor substrate onto which a plurality of first light-emitting elements have been transferred. FIG. 13 is a plan view showing a second donor substrate onto which a plurality of second light-emitting elements have been transferred. FIG. 14 is a plan view showing a third donor substrate onto which a plurality of third light-emitting elements have been transferred. FIG. 15 is a schematic cross-sectional view for illustrating a process of transferring the plurality of light-emitting elements disposed on the donor substrate to the display panel PN. FIG. 16 is a plan view showing the display panel having the plurality of light-emitting elements transferred thereto.

Referring to FIG. 6, the plurality of light-emitting elements ED is formed on a wafer 200. The wafer 200 may be made of a material such as sapphire, silicon (Si), silicon carbide (SiC), or gallium arsenide (GaAs). However, embodiments of the present disclosure are not limited thereto. Each of the plurality of light-emitting elements ED formed on the wafer 200 may have the same configuration as that of the light-emitting element ED in FIG. 2. Each of the plurality of light-emitting elements ED may be an LED or a micro-LED, and may have a horizontal, vertical, or flip chip structure.

The plurality of light-emitting elements ED formed on the wafer 200 are transferred from the wafer 200 to a donor substrate 300 in a first transfer process, and are transferred from the donor substrate 300 to a display panel PN (see FIG. 15) in a second transfer process. In other words, the plurality of light-emitting elements ED are transferred from the wafer 200 to the donor substrate 300 and then are transferred from the donor substrate 300 to the display panel PN (see FIG. 15). Thus, a manufacturing process of the display device may be completed.

The wafer 200 may include an active area 20A and a peripheral area 20B surrounding the active area 20A. The active area 20A is the area where the plurality of light-emitting elements ED are formed, and the peripheral area 20B is an area where a plurality of alignment keys 25 are disposed.

The plurality of light-emitting elements ED may be arranged in a matrix manner in a first direction (an X-axis direction) and a second direction (a Y-axis direction) in the active area 20A. The active area 20A may have a rectangular area due to the arrangement of the plurality of light-emitting elements ED in the matrix shape. However, embodiments of the present disclosure are not limited thereto. When the active area 20A includes the rectangular area, the active area may include both opposing sides in a column direction and both opposing sides in a row direction. In this regard, the first direction may be referred to as a width direction or a row direction of the wafer, and the second direction may be referred to as a length direction or a column direction of the wafer.

The plurality of alignment keys 25 may include a macro key 21 and a micro key 23.

The macro key 21 may be disposed on a position of the peripheral area 20B adjacent to each of four corners of the active area 20A. A plurality of macro keys 21 may be arranged for alignment accuracy. For example, the macro key 21 may be disposed on a position of the peripheral area 20B adjacent to each of both opposing corners in the row direction of the active area 20A in each of both opposing portions in the column direction of the peripheral area 20B of the wafer. The macro key 21 may be used to align the wafer 200 and the donor substrate 300 with each other.

The micro key 23 may be disposed in each of left and right portions of the active area 20A. The left and right portions of the active area 20A may be arranged in a scanning direction of the laser beam in the first transfer process using a laser beam.

The plurality of micro keys 23 may be disposed for alignment accuracy. For example, the micro key 23 may include a first micro key 23a and a second micro key 23b arranged at a predetermined interval in the length direction of the wafer 200 from the first micro key 23a. In FIG. 6, the two micro keys 23 may be disposed on each of both opposing portions in the row direction (X-direction) of the peripheral area 20B. The two micro keys 23 may be respectively disposed on both opposing positions in the column direction (Y-direction) of each of the two opposing portions in the row direction of the peripheral area 20B. For example, the micro key 23 may include a first micro key 23a and a second micro key 23b respectively disposed on both opposing positions in the column direction (Y-direction) of each of the two opposing portions in the row direction (X-direction) of the peripheral area 20B. The first micro key 23a and the second micro key 23b may be spaced from each other by a predefined spacing in the column direction (Y-direction).

More specifically, one cycle the laser beam scans the active area 20A includes four scan times. In this regard, one first micro key 23a may be disposed at a first scan start point where a first scan starts, while the other first micro key 23a may be disposed at a first scan end point where the first scan ends. Additionally, one second micro key 23b may be disposed at a third scan start point where a third scan begins, while the other second micro key 23b may be disposed at a third scan end point where the third scan ends. Description thereof will continue in FIG. 9 later.

The macro key 21 and the micro key 23 may be formed on the wafer 200 in a process of forming the plurality of light-emitting elements ED on the wafer 200. The macro key 21 and the micro key 23 may be formed to have different shapes and sizes. For example, the macro key 21 may have a circular shape. However, embodiments of the present disclosure are not limited thereto. The macro key 21 may be embodied as a single pattern including the circular shape.

The micro key 23 may have an array structure to improve alignment accuracy. For example, each of the first micro key 23a and the second micro key 23b may be embodied as a collection of a plurality of island patterns 23M arranged in a matrix manner in the first direction, (e.g., X-axis direction), and the second direction (e.g., Y-axis direction). Thus, each of the first micro key 23a and the second micro key 23b may be patterned to be formed as an arrangement of the island patterns. Each of the individual island patterns 23M constituting each of the first micro key 23a and the second micro key 23b may have a circular shape. However, embodiments of the present disclosure are not limited thereto.

Furthermore, one of the plurality of island patterns 23M constituting the micro key 23 may have a size at least equal to or smaller than a size of the light-emitting element ED.

The micro key 23 may be transferred to the donor substrate 300 when the plurality of light-emitting elements ED formed on the wafer 200 is transferred to the donor substrate 300 (see FIG. 7). The macro key 21 and the micro key 23 may be formed on the wafer 200 in a process of forming the plurality of light-emitting elements ED on the wafer 200. When the macro key 21 and the micro key 23 together with the plurality of light-emitting elements ED are formed on the wafer, each of the macro key 21 and the micro key 23 may include the same materials as at least some of the materials constituting the light-emitting element ED. In another example, the macro key 21 and the micro key 23 may be formed in a separate process from a process of forming the light-emitting element ED.

The micro key 23 is composed of the plurality of island patterns 23M densely arranged in an array form. Thus, there is a possibility that foreign matter may be generated during the second transfer process. More specifically, the micro key 23 is composed of the plurality of island patterns 23M densely arranged in an array form, such that an epitaxial layer of the wafer 200 in an area of the micro key 23 is not entirely removed in the laser lift-off process. Thus, the remaining portion of the epitaxial layer in the micro key area may be transferred to the display panel PN. Thus, the foreign matter is generated during the second transfer process of transferring the light-emitting elements ED to the display panel PN. For this reason, according to an embodiment of the present disclosure, in a process of forming the micro key 23, a portion of the epitaxial layer of the wafer 200 exposed between the neighboring island patterns 23M is removed in an etching process. This may prevent the epitaxial layer in the micro key 23 from acting as a foreign matter during the second transfer process of the light-emitting elements ED from the donor substrate to the display panel PN, or at least reduce the likelihood of this occurring.

Referring to FIG. 7, the donor substrate 300 may include a base substrate 305, an adhesive layer 310, and a plurality of posts 325. In one example, the donor substrate 300 may have a plurality of posts 325 disposed on the base substrate 305. The base substrate 305 supports the adhesive layer 310 and the plurality of posts 325 thereon, and may be made of a hard material. The adhesive layer 310 disposed on the base substrate 305 may fix the plurality of light-emitting elements ED transferred from the wafer 200 to the donor substate 300 to the donor substrate 300.

The base substrate 305 may include a transferred area and a non-transferred area. The transferred area may be an area on which the plurality of posts 325 are disposed. The transferred area may be an area to which the plurality of light-emitting elements ED and the micro keys 23 are transferred. The non-transferred area may be an area to which the light-emitting elements ED and the micro keys 23 are not transferred and an area on which the post for aligning the wafer 200 and the donor substrate 300 to each other is disposed.

Each of the plurality of posts 325 may have a shape that protrudes from the adhesive layer 310 and may be made of the same material as that of the adhesive layer 310. In one example, the plurality of posts 325 may be integrated with the adhesive layer 310. The plurality of posts 325 may include a first post 315, a second post 313, and a third post 320.

The first post 315 may include a plurality of posts disposed on an inner area of the adhesive layer 310 and arranged in a matrix manner in the X-axis direction as the first direction and the Y-axis direction as the second direction. In this regard, the first direction may be referred to as the width direction or the row direction of the donor substrate 300, and the second direction may be referred to as the length direction or the column direction of the donor substrate 300.

Each of the plurality of light-emitting elements ED to be transferred to the display panel PN (see FIG. 15) may be transferred to each of the plurality of first posts 315. In one example, each light-emitting element ED may be positioned in a corresponding manner to each first post 315. Neighboring first posts 315 may be arranged to be spaced apart from each other by a first width P1. The first width P1 may be 1 pixel pitch.

The second post 313 may include a plurality of second posts 313 respectively disposed on positions adjacent to corners of the adhesive layer 310. Each of the plurality of second posts 313 may be positioned in a corresponding manner to each of the macro keys 21 of the wafer 200 (see FIG. 6).

Each of the plurality of third posts 320 may be positioned in a corresponding manner to each of the micro keys 23 of the wafer 200 (see FIG. 6). In FIG. 7, the two third posts 320 may be disposed on each of two opposing portions in the row direction (X-direction) of an area of the adhesive layer 310. The two third posts 320 may be respectively disposed on both opposing positions in the column direction (Y-direction) of each of the two opposing portions in the row direction of the area of the adhesive layer 310. Each of the plurality of micro key 23 of the wafer 200 may be transferred to each of the plurality of third posts 320 disposed on the donor substrate 300. The micro keys 23 respectively transferred to the plurality of third posts 320 along with the light-emitting elements ED respectively transferred to the plurality of first posts 315 may be transferred to the display panel in the second transfer process. Accordingly, it is important to arrange the plurality of micro keys 23 so as not to interfere with the light-emitting elements ED transferred to the display panel PN.

To this end, the plurality of third posts 320 according to another embodiment of the present disclosure is spaced apart from the outermost first post 315 disposed closest to the third post 320 among the first posts 315 by a second width P2. The second width P2 may be larger than the first width P1. For example, the second width P2 may be a rational number (greater than 1) times (e.g., 1.5 times, 2 times, 2.5 times, 3 times, etc.) of the first width P1.

The donor substrate 300 may include a plurality of donor substrates. For example, the plurality of donor substrates may include a first donor substrate for transferring a plurality of light-emitting elements ED that emits light of a first color, a second donor substrate for transferring a plurality of light-emitting elements ED that emits light of a second color, and a third donor substrate for transferring a plurality of light-emitting elements ED that emits light of a third color. In this regard, the first color, the second color, and third color may be red, green, and blue, respectively.

Referring to FIG. 8 and FIG. 9, the wafer 200 and the donor substrate 300 are placed in process equipment for the laser lift-off process such that the wafer 200 is located on top of the donor substrate 300. The plurality of posts 325 on the donor substrate 300 and the light-emitting elements ED and the micro keys 23 of the wafer 200 may be arranged to face each other.

After the alignment of the wafer 200 and the donor substrate 300 with each other has been completed, the first transfer process is performed to transfer the plurality of light-emitting elements ED on the wafer 200 to the donor substrate 300. Referring to FIG. 8, in the first transfer process, the process equipment irradiates the laser beam as indicated by an arrow to the plurality of light-emitting elements ED to be transferred from a back surface of the wafer 200 to the donor substrate 300. The plurality of light-emitting elements ED as irradiated with the laser beam may be detached from the wafer 200 and then may be adhered respectively to the plurality of first posts 315 of the donor substrate 300.

At this time, the plurality of micro keys 23 of the wafer 200 may be transferred respectively to the third posts 320 of the donor substrate 300 at the same time as when the light-emitting elements ED are transferred respectively to the plurality of first posts 315 of the donor substrate 300.

Referring to FIG. 9, the first transfer process may include scanning the wafer 200 with the laser beam LB. FIG. 9 shows only the wafer 200 for convenience of illustration.

Specifically, in the first transfer scheme using the laser lift-off scheme, the laser beam LB scans the wafer 200. Specifically, one side end of the wafer 200 in a first row may be a first scan start point, and the other side end opposite thereto of the wafer in the first row may be a first scan end point. In the scheme in which the laser beam LB scans the wafer, the laser beam LB may travel from the first scan start point in the X-axis direction as the first direction, and may reach the first scan end point. This is a first scan. Next, the laser beam LB travels by a predetermined distance in the Y-axis direction as the second direction and reaches a second scan start point in a second row and travels therefrom in the first direction and reaches a second scan end point in the second row. This is a second scan.

Next, the laser beam LB travels by a predetermined distance in the Y-axis direction as the second direction and reaches a third scan start point in a third row and travels therefrom in the first direction and reaches a third scan end point in the third row. This is a third scan. Next, the laser beam LB travels by a predetermined distance in the Y-axis direction as the second direction and reaches a fourth scan start point in a fourth row and travels therefrom in the first direction and reaches a fourth scan end point in the fourth row. This is a fourth scan. In other words, the laser scan may be performed in a manner such that the laser beam LB is irradiated to the wafer while traveling from the scan start point to the scan end point and then returns to the scan start point in a subsequent row.

Referring to FIG. 6, FIG. 9, and FIG. 10 together, the micro keys 23 according to an embodiment of the present disclosure may be disposed in each of the left and right portions of the active area 20A. In other words, the micro keys 23 may be arranged in the same direction as the scanning direction of the laser beam LB in the first transfer process using a laser.

A cycle CSC2 for which the laser beam LB scans the wafer 200 in the active area 20A in order to transfer the light-emitting elements ED from the active area 20A to the donor substrate 300 may include four times of scans.

Among the micro keys 23, the left first micro key 23a may be spaced away from the light-emitting element ED disposed at the first scan start point where the first scan begins, while the right first micro key 23a may be spaced away from the light-emitting element ED disposed at the first scan end point where the first scan ends. Additionally, among the micro keys 23, the left second micro key 23b may be spaced away from the light-emitting element ED disposed at the third scan start point where the third scan begins, while the right second micro key 23b may be spaced away from the light-emitting element ED disposed at the third scan end point where the third scan ends.

Accordingly, the first micro keys 23a and the second micro keys 23b may be transferred to the donor substrate 300 at the same time as when the light-emitting elements ED are transferred to the donor substrate 300. Thus, no separate laser scan is required to transfer the first micro key 23a and the second micro key 23b onto the donor substrate 300.

Accordingly, a production amount of the light-emitting elements as affected by the number of times the laser beam scans the wafer may be increased. For example, as the number of times the laser beam scans the wafer decreases from 6 to 4, a time taken to lift off the plurality of light-emitting elements from the wafer may decrease. As the time required to lift off the plurality of light-emitting elements is reduced, the production amount of the light-emitting element may be increased within the same process operating time.

As the micro keys 23 are arranged in the same direction as the scanning direction of the laser beam LB, the micro keys 23 and the light-emitting element ED may be scanned with the laser beam LB and thus may be detached from the wafer and thus may be transferred to the donor substrate 300 at the same time. In this regard, as shown in FIG. 9 and FIG. 10, while the laser beam LB scans the micro key 23 in an overlapping manner with the micro key 23, the laser mask including a shape in which the plurality of mask patterns MPT are arranged may overlap with the micro key 23. The plurality of mask patterns are arranged in longitudinal and width directions of the laser mask.

In this case, the laser beam LB may travel only until a Y-axis center of the mask pattern located at an end in the Y-direction or the column direction of the laser mask including the plurality of mask patterns MPT and a Y-axis center of one of the island patterns arranged in a first column among the plurality of island patterns 23M of the micro key may exactly overlap each other. Accordingly, the island patterns 23M disposed in second to fourth columns may be prevented from being damaged by the laser beam LB, or at least the likelihood of damage is reduced.

A size W2 of each of the plurality of island patterns 23M may be at least equal to or smaller than the size W1 of the light-emitting element ED. Accordingly, both the light-emitting elements and the micro keys may be transferred to the donor substrate using a single laser mask. Accordingly, the accuracy of the position to which the light-emitting element is transferred to the donor substrate and, thus, the transfer precision may be improved. Furthermore, mask patterns designed based on various pitches may be applied to a single laser mask, thereby diversifying a mask model and thus improving the lifespan of the laser mask.

FIG. 11A shows a timing diagram of an operation of scanning a wafer using a laser beam in a general laser lift-off manner in accordance with one embodiment of the present disclosure. According to FIG. 11A, during a period for which the laser beam LB is irradiated to the wafer while traveling from the scan start point to the scan end point, a period for which the laser beam is irradiated on the wafer may be defined as a shot period, and each of a period before the laser beam starts to be irradiated and a period after the laser beam has reached the scan end point and then for which the laser beam stops to being irradiated and travels to a next row may be defined as a shot blank period. That is, the general laser lift-off scheme may include the shot period and the shot blank periods.

Alternatively, FIG. 11B shows a timing diagram of an operation of scanning a wafer using a laser beam in the laser lift-off scheme according to another embodiment of the present disclosure. Referring to FIG. 11B, the shot period which is the period for which the laser beam is irradiated on the wafer is performed for the same time as that in the general laser lift-off scheme. In one example, the laser lift-off scheme according to the present disclosure includes an additional shot period between shot blank periods adjacent to each other. For the additional shot period, the laser beam is irradiated on the wafer to transfer the micro keys 23 arranged in the same direction as the scanning direction of the laser beam.

Referring to FIG. 12 to FIG. 14, the donor substrate 300 on which the plurality of light-emitting elements ED have been placed through the first transfer process may include a plurality of donor substrates 300R, 300G, and 300B. For example, the plurality of donor substrates 300R, 300G, and 300B may include a first donor substrate 300R (see FIG. 12), a second donor substrate 300G (see FIG. 13), and a third donor substrate 300B (see FIG. 14).

Referring to FIG. 12, the first donor substrate 300R may include a plurality of first light-emitting elements ED_1 that emit light of the first color. In one example, the first color may be red. The adjacent first light-emitting elements ED_1 may be arranged to be spaced apart from each other by the first width P1. The first width P1 may be the 1 pixel pitch in size.

A first micro key pattern 23_a1 and 23_a2 may be disposed on the first donor substrate 300R. The first micro key pattern 23_a1 and 23_a2 may include a first portion 23_a1 of the first micro key pattern disposed in a left area of the first donor substrate 300R and a second portion 23_a2 of the first micro key pattern disposed in a right area thereof. A plurality of first portions 23_a1 of the first micro key pattern may be arranged in the Y-axis direction in the left area. A plurality of second portions 23_a2 of the first micro key pattern may be arranged in the Y-axis direction in the right area. In one example, the first portion 23_a1 of the first micro key pattern and the second portion 23_a2 of the first micro key pattern may be arranged to be spaced apart from each other in the row direction of the display panel PN.

The first micro key pattern 23_a1 and 23_a2 may be disposed at a position spaced apart from the outermost first light-emitting element ED_1 among the plurality of first light-emitting element ED_1 by the second width P2. The second width P2 may be larger than the first width P1 as the pixel pitch size. For example, the second width P2 may be larger than the first width P1. For example, the second width P2 may be a rational number (greater than 1) times (e.g., 1.5 times, 2 times, 2.5 times, 3 times, etc.) of the first width P1.

Referring to FIG. 13, the second donor substrate 300G may include a plurality of second light-emitting elements ED_2 that emit light of a second color. In one example, the second color may be green. The second light-emitting elements ED_2 may be arranged to be spaced apart from each other by the first width P1. The first width P1 may be the pixel pitch size.

A second micro key pattern 23_b1 and 23_b2 may be disposed on the second donor substrate 300G. The second micro key pattern 23_b1 and 23_b2 may include a first portion 23_b1 of the second micro key pattern disposed in a left area of the second donor substrate 300G and a second portion 23_b2 of the second micro key pattern disposed in a right area thereof. A plurality of first portions 23_b1 of the second micro key pattern may be arranged in the Y-axis direction in the left area. A plurality of second portions 23_b2 of the second micro key pattern may be arranged in the Y-axis direction in the right area. In one example, the first portion 23_b1 of the second micro key pattern and the second portion 23_b2 of the second micro key pattern may be arranged to be spaced apart from each other in the row direction of the display panel PN.

The second micro key pattern 23_b1 and 23_b2 may be disposed at a position spaced apart from the outermost second light-emitting element ED_2 of the plurality of second light-emitting element ED_2 by the second width P2. For example, the second width P2 may be larger than the first width P1. For example, the second width P2 may be a rational number (greater than 1) times (e.g., 1.5 times, 2 times, 2.5 times, 3 times, etc.) of the first width P1.

Referring to FIG. 14, the third donor substrate 300B may include a plurality of third light-emitting elements ED_3 that emit light of a third color. In one example, the third color may be blue. The third light-emitting elements ED_3 may be arranged to be spaced apart from each other by the first width P1. The first width P1 may be the 1 pixel pitch in size.

A third micro key pattern 23_c1 and 23_c2 may be disposed on the third donor substrate 300B. The third micro key pattern 23_c1 and 23_c2 may include a first portion 23_c1 of the third micro key pattern disposed in a left area of the third donor substrate 300B and a second portion 23_c2 of the third micro key pattern disposed in a right area thereof. A plurality of first portions 23_c1 of the third micro key pattern may be arranged in the Y-axis direction in the left area. The plurality of second portions 23_c2 of the third micro key pattern may be arranged in the Y-axis direction in the right area. In one example, the first portion 23_c1 of the third micro key pattern and the second portion 23_c2 of the third micro key pattern may be arranged to be spaced apart from each other in the row direction of the display panel PN.

The third micro key pattern 23_c1 and 23_c2 may be disposed at a position spaced apart from the outermost third light-emitting element ED_3 among the plurality of third light-emitting element ED_3 by the second width P2. The second width P2 may be larger than the first width P1 as the pixel pitch size. For example, the second width P2 may be larger than the first width P1. For example, the second width P2 may be a rational number (greater than 1) times (e.g., 1.5 times, 2 times, 2.5 times, 3 times, etc.) of the first width P1.

Referring to FIG. 15 and FIG. 16, the second transfer process is performed to transfer the plurality of light-emitting elements ED (e.g., LEDs) from the donor substrate 300 to the display panel PN. In FIG. 15, for convenience of description, the description is based on a single donor substrate 300. However, the same description may be equally applied to the first donor substrate 300R, the second donor substrate 300G, and the third donor substrate 300B.

Referring to FIG. 15, the plurality of light-emitting elements ED of the donor substrate 300 is transferred to the display panel PN to manufacture the display device. For example, the donor substrate 300 is placed on the display panel PN so that a top surface of each of the plurality of light-emitting elements of the donor substrate 300 and a top surface of the display panel PN face each other. Next, the donor substrate 300 is displaced downwardly to contact the display panel PN to transfer the plurality of light-emitting elements ED of the donor substrate 300 to the display panel PN. Then, the plurality of light-emitting elements ED may be transferred to a first area of the display panel PN, while the micro keys 23 may be transferred to a second area of the display panel PN. The first area may be a display area or a light-emitting area where the light-emitting elements ED are not disposed. The second area may be a non-display area or a non-light-emitting area. In this regard, the plurality of light-emitting elements ED and the plurality of micro keys 23 on the donor substrate 300 may be transferred onto the display panel PN such that the positions thereof are not changed.

A display panel formed in the second transfer process according to another embodiment of the present disclosure may be formed in a three-sets stamping manner. This will be described below with reference to FIG. 16.

In the three-sets stamping scheme, one set stamping may be completed by transferring the light-emitting elements and the micro key patterns disposed on each of the plurality of donor substrates that respectively emit light beams of different colors to the display panel PN.

For example, referring to FIG. 16, the first light-emitting elements ED_1 and the first micro key pattern 23_a1 and 23_a2 of the first donor substrate 300R, the second light-emitting elements ED_2 and the second micro key pattern 23_b1 and 23_b2 of the second donor substrate 300G, and the third light-emitting elements ED_3 and the third micro key pattern 23_c1 and 23_c2 of the third donor substrate 300B are transferred to a first set area of the display panel PN in the second transfer process. Thus, a stamping of a first set ST1 may be completed. As shown in FIG. 16, after the stamping of the first set ST1, the first light-emitting element ED_1, the second light-emitting element ED_2, and the third light-emitting element ED_3 are arranged in parallel in the row direction.

The first light-emitting element ED_1, the second light-emitting element ED_2, and the third light-emitting element ED_3 transferred onto the display panel PN may emit light beams of different colors, respectively. For example, the light beams of the different colors may emit red, green, and blue light beams. Each of the first to third light-emitting elements ED_1, ED_2, and ED_3 may constitute a sub-pixel.

The plurality of light-emitting elements ED_1, ED_2, and ED_3 transferred on the display panel PN in the stamping of the first set ST1 may be arranged in an area from first to fifth columns from a left end of the display panel PN.

In this regard, the first micro key pattern 23_a1 and 23_a2 of the first donor substrate 300R, the second micro key pattern 23_b1 and 23_b2 of the second donor substrate 300G, and the third micro key pattern 23_c1 and 23_c2 of the third donor substrate 300B may be arranged in one direction. In this regard, one of the first micro key pattern 23_a1 and 23_a2, the second micro key pattern 23_b1 and 23_b2, and the third micro key pattern 23_c1 and 23_c2 may be spaced apart from the outermost one of the outermost light-emitting elements ED_1, ED_2, and ED_3 by the second width P2. For example, the second width P2 may be larger than the first width P1. For example, the second width P2 may be a rational number (greater than 1) times (e.g., 1.5 times, 2 times, 2.5 times, 3 times, etc.) of the first width P1 equal to the 1 pixel pitch.

Next, the first light-emitting elements ED_1 and the first micro key pattern 23_a1 and 23_a2 of the first donor substrate 300R, the second light-emitting elements ED_2 and the second micro key pattern 23_b1 and 23_b2 of the second donor substrate 300G, and the third light-emitting elements ED_3 and the third micro key pattern 23_c1 and 23_c2 of the third donor substrate 300B are transferred to a second set area of the display panel PN in the second transfer process. Thus, a stamping of a second set ST2 in an overlapping manner with the first set ST1 may be completed. As shown in FIG. 16, after stamping of the second set ST2, the first light-emitting element ED_1, the second light-emitting element ED_2 and the third light-emitting element ED_3 in the second set ST2 are arranged in parallel in the row direction. In addition, the second set area has an overlapping area overlapping with the first set area, and the micro key pattern in the overlapping region is located in the non-light-emitting area between the light-emitting elements adjacent to each other.

Then, the plurality of light-emitting elements ED_1, ED_2, and ED_3 transferred in the second set ST2 can be arranged from six to tenth columns to the right side of the third light-emitting element ED_3 transferred to fifth column in the first set ST1.

Each of the first micro key pattern 23_a1 and 23_a2 of the first donor substrate 300R, the second micro key pattern 23_b1 and 23_b2 of the second donor substrate 300G, and the third micro key pattern 23_c1 and 23_c2 of the third donor substrate 300B transferred from the second set ST2 may be arranged in a line extending a direction from left to right.

In this regard, the first micro key pattern 23_a1 and 23_a2, the second micro key pattern 23_b1 and 23_b2, and the third micro key pattern 23_c1 and 23_c2 may be spaced apart from each of the left outermost or right outermost light-emitting elements ED_1, ED_2, and ED_3 by the second width P2. For example, the second width P2 (see FIGS. 12, 13, and 14) may be larger than the 1 pixel pitch.

Accordingly, the respective first portions 23_a1, 23_b1 and 23_c1 of the first to third micro key patterns transferred onto the left side of the area of the second set ST2 may be disposed between the third light-emitting element ED_3 transferred to the fourth column of the area of the first set ST1 and the first light-emitting element ED_1 transferred to the fifth column of the area of the second set ST2. In this regard, the space between the third light-emitting element ED_3 transferred to the fourth column and the first light-emitting element ED_1 transferred to the fifth column may be an active chip area as a non-light-emitting area included in the display area.

In this regard, the first portions 23_a1 and 23_b1 and 23_c1 of the first to third micro key patterns should have no interference with the operation of the light-emitting elements ED_3 and ED_1 adjacent thereto, and thus should be arranged within the pixel pitch and should not go beyond the pixel pitch.

Furthermore, when the stamping of the second set ST2 has been completed, the second portions 23_a2, 23_b2, and 23_c2 of the first to third micro key patterns transferred onto the right area of the area of the first set ST1 may be disposed between the third light-emitting element ED_3 transferred to the sixth column of the area of the second set ST2 and the first light-emitting element ED_1 transferred to the seventh column of the area of the second set ST2. In this regard, the space between the third light-emitting element ED_3 transferred to the sixth column of the area of the second set ST2 and the first light-emitting element ED_1 transferred to the seventh column of the area of the second set ST2 may be an active chip area as a non-light-emitting area included in the display area.

In this regard, the second portions 23_a2, 23_b2, and 23_c2 of the first to third micro key patterns should have no interference with the operation of the light-emitting elements ED_3 and ED_1 adjacent thereto, and thus should be arranged within the pixel pitch and should not go beyond the pixel pitch.

Next, the first light-emitting elements ED_1 and the first micro key pattern 23_a1 and 23_a2 of the first donor substrate 300R, the second light-emitting elements ED_2 and the second micro key pattern 23_b1 and 23_b2 of the second donor substrate 300G, and the third light-emitting elements ED_3 and the third micro key pattern 23_c1 and 23_c2 of the third donor substrate 300B are transferred to a third set area of the display panel PN in the second transfer process. Thus, a stamping of a third set ST3 may be completed. As shown in FIG. 16, after stamping of the third set ST3, the first light-emitting element ED_1, the second light-emitting element ED_2 and the third light-emitting element ED_3 in the third set ST3 are arranged in parallel in the row direction. In addition, the third set area has an overlapping area overlapping with the second set area, and the micro key pattern in the overlapping region is located in the non-light-emitting area between the light-emitting elements adjacent to each other.

Then, the plurality of light-emitting elements ED_1, ED_2, and ED_3 transferred on the display panel PN in the stamping of the third set ST3 may be arranged from the eleventh to fifteenth columns to the right of the third light-emitting element ED_3 transferred in the tenth column of the second set ST2.

Each of the first micro key pattern 23_a1 and 23_a2 of the first donor substrate 300R, the second micro key pattern 23_b1 and 23_b2 of the second donor substrate 300G, and the third micro key pattern 23_c1 and 23_c2 of the third donor substrate 300B transferred from the third set ST3 may be arranged in a line extending a direction from left to right.

In this regard, the first micro key pattern 23_a1 and 23_a2, the second micro key pattern 23_b1 and 23_b2, and the third micro key pattern 23_c1 and 23_c2 may be spaced apart from each of the left outermost or right outermost light-emitting elements ED_1, ED_2, and ED_3 by the second width P2. For example, the second width P2 (see FIGS. 12, 13, and 14) may be larger than the 1 pixel pitch.

Accordingly, the respective first portions 23_a1, 23_b1 and 23_c1 of the first to third micro key patterns transferred onto the left side of the area of the third set ST3 may be disposed between the third light-emitting element ED_3 transferred to the ninth column of the area of the second set ST2 and the first light-emitting element ED_1 transferred to the tenth column of the area of the third set ST3. In this regard, the space between the third light-emitting element ED_3 transferred to the ninth column of the area of the second set ST2 and the first light-emitting element ED_1 transferred to the tenth column of the area of the third set ST3 may be an active chip area as a non-light-emitting area included in the display area.

In this regard, the respective first portions 23_a1 and 23_b1 and 23_c1 of the first to third micro key patterns should have no interference with the operation of the light-emitting elements ED_3 and ED_1 adjacent thereto, and thus should be arranged within the pixel pitch and should not go beyond the pixel pitch.

Furthermore, when the stamping of the third set ST3 has been completed, the second portions 23_a2, 23_b2, and 23_c2 of the first to third micro key patterns transferred onto the right side area of the area of the third set ST3 may be disposed on the right side of the third light-emitting element ED_3 transferred to the fifteenth column of the area of the third set ST3. Although three-sets stamping scheme are shown above, one-set stamping scheme, two-sets stamping scheme or more-sets stamping scheme are also possible.

In other words, the micro key pattern is disposed at a position spaced from by a spacing larger than the 1 pixel pitch from the outermost light-emitting element located at each of both opposing ends in the row direction of an array area of the plurality of light-emitting elements. Accordingly, when the second transfer process has been performed to transfer the light-emitting elements onto the plurality of set areas of the display panel, the micro key pattern may be disposed in the active chip area as the non-light-emitting area between adjacent ones of the light-emitting elements respectively transferred to adjacent ones of the plurality of set areas.

In one example, the order of arrangement of the micro key patterns in the left area may be configured such that the micro key pattern on the donor substrate on which the red light-emitting elements are disposed, the micro key pattern on the donor substrate on which the green light-emitting elements are disposed, and the micro key pattern on the donor substrate on which the blue light-emitting elements are disposed may be arranged in this order, while the order of arrangement of the micro key patterns in the right area may be configured such that the micro key pattern on the donor substrate on which the red light-emitting elements are disposed, the micro key pattern on the donor substrate on which the green light-emitting elements are disposed, and the micro key pattern on the donor substrate on which the blue light-emitting elements are disposed may be arranged in this order. However, embodiments of the present disclosure are not limited thereto. In another example, the order of arrangement of the micro key patterns in the left area may be configured such that the micro key pattern on the donor substrate on which the red light-emitting elements are disposed, the micro key pattern on the donor substrate on which the green light-emitting elements are disposed, and the micro key pattern on the donor substrate on which the blue light-emitting elements are disposed may be arranged in this order, while the order of arrangement of the micro key patterns in the right area may be configured such that the micro key pattern on the donor substrate on which the blue light-emitting elements are disposed, the micro key pattern on the donor substrate on which the green light-emitting elements are disposed, and the micro key pattern on the donor substrate on which the red light-emitting elements are disposed may be arranged in this order.

In this regard, when the order of arrangement of the micro key patterns in each of the left and right areas is configured such that the micro key pattern on the donor substrate on which the red light-emitting elements are disposed, the micro key pattern on the donor substrate on which the green light-emitting elements are disposed, and the micro key pattern on the donor substrate on which the blue light-emitting elements are disposed may be arranged in this order, a spacing between the outermost light-emitting element and the micro key pattern in the left area may be different from a spacing between the outermost light-emitting element and the micro key pattern in the right area. Alternatively, when the order of arrangement of the micro key patterns in the left area is configured such that the micro key pattern on the donor substrate on which the red light-emitting elements are disposed, the micro key pattern on the donor substrate on which the green light-emitting elements are disposed, and the micro key pattern on the donor substrate on which the blue light-emitting elements are disposed may be arranged in this order, while the order of arrangement of the micro key patterns in the right area may be configured such that the micro key pattern on the donor substrate on which the blue light-emitting elements are disposed, the micro key pattern on the donor substrate on which the green light-emitting elements are disposed, and the micro key pattern on the donor substrate on which the red light-emitting elements are disposed may be arranged in this order, a spacing between the outermost light-emitting element and the micro key pattern in the left area may be equal to a spacing between the outermost light-emitting element and the micro key pattern in the right area.

A display device including an LED (light-emitting diode) and a method for manufacturing the display device according to some aspects and embodiment of the present disclosure may be set forth below.

A first aspect of the present disclosure provides a display device comprising: a display panel including a light-emitting areas and a non-light-emitting areas arranged alternately with each other in a row direction and/or a column direction; a plurality of light-emitting elements disposed in the light-emitting areas of the display panel and arranged in a plurality of rows and a plurality of columns; and a plurality of micro keys disposed in the non-light-emitting area between the light-emitting areas adjacent to each other in the row direction and/or the column direction.

In accordance with some embodiments of the display device of the present disclosure, each of the plurality of light-emitting elements is arranged to be spaced apart from each other by a first width of 1 pixel pitch, wherein each of the micro keys is spaced apart from the light emitting element disposed at an outermost of the display panel among the plurality of light-emitting elements by a second width greater than the first width.

In accordance with some embodiments of the display device of the present disclosure, the second width is rational number times of the 1 pixel pitch, wherein the rational number is greater than 1.

In accordance with some embodiments of the display device of the present disclosure, the micro keys include: a first micro key disposed on the display panel; and a second micro key disposed on the display panel and spaced apart from the first micro key in the column direction of the display panel.

In accordance with some embodiments of the display device of the present disclosure, the micro keys are arranged in the same direction as a direction in which a laser beam travels.

A second aspect of the present disclosure provides a method for manufacturing a display device, the method comprising: a first transfer step of transferring a plurality of light-emitting elements, a plurality of macro keys, and a plurality of micro keys disposed on the wafer onto a donor substrate; providing a display panel including a plurality of light-emitting areas and a plurality of non-light-emitting areas arranged alternately with each other in a row direction and/or a column direction; and a second transfer step of transferring the plurality of light-emitting elements and the plurality of micro keys from the donor substrate to the display panel, wherein the plurality of micro keys are transferred to the non-light-emitting area between the light-emitting elements adjacent to each other.

In accordance with some embodiments of the method for manufacturing the display device of the present disclosure, the micro keys include a first micro key and a second micro key arranged to be spaced apart from each other in a column direction of the display panel.

In accordance with some embodiments of the method for manufacturing the display device of the present disclosure, the first transfer step includes: a first scan in which a laser beam is irradiated to the wafer while traveling from a first scan start point at one end of the wafer to a first scan end point at the other end opposite thereto of the wafer in a first row of the wafer; a second scan in which the laser beam travels from the first row in a column direction to reach a second scan start point at the other end of the wafer in a second row of the wafer and, is irradiated to the wafer while traveling from the second scan start point to a second scan end point at one end opposite thereto of the wafer in the second row of the wafer; a third scan in which the laser beam travels from the second row in the column direction to reach a third scan start point at one end of the wafer in a third row of the wafer, and is irradiated to the wafer while traveling from the third scan start point to a third scan end point at the other end opposite thereto of the wafer in the third row of the wafer; and a fourth scan in which the laser beam travels from the third row in the column direction to reach a fourth scan start point at the other end of the wafer in a fourth row of the wafer and is irradiated to the wafer while traveling from the fourth scan start point to a fourth scan end point at one end opposite thereto of the wafer in the fourth row of the wafer.

In accordance with some embodiments of the method for manufacturing the display device of the present disclosure, the first micro key includes two first micro keys respective disposed at the first scan start point and the first scan end point, wherein the second micro key includes two second micro keys respective disposed at the third scan start point and the third scan end point.

In accordance with some embodiments of the method for manufacturing the display device of the present disclosure, each of the micro keys has an array structure in which a plurality of island patterns are arranged in a matrix manner.

In accordance with some embodiments of the method for manufacturing the display device of the present disclosure, one of the plurality of island patterns has a size equal to or smaller than a size of each of the light-emitting elements.

In accordance with some embodiments of the method for manufacturing the display device of the present disclosure, the plurality of light-emitting elements arranged adjacently are arranged to be spaced apart from each other by a first width equal to 1 pixel pitch, wherein each of the micro keys is spaced apart from the light-emitting element disposed at closest with the micro keys among the plurality of light-emitting elements by a second width greater than the first width.

In accordance with some embodiments of the method for manufacturing the display device of the present disclosure, the second width is rational number times of the 1 pixel pitch, wherein the rational number is greater than 1.

In accordance with some embodiments of the method for manufacturing the display device of the present disclosure, each of the micro keys has an array structure in which a plurality of island patterns are arranged in a matrix manner, wherein the laser beam is irradiated through a laser mask to the wafer, wherein the laser mask includes a plurality of mask patterns and at least partially overlapping the micro key, wherein the laser beam travels until a center in the column direction of one mask pattern located at an end in the column direction of the laser mask including the plurality of mask patterns and a center in the column direction of one of the island patterns arranged in a first column among the plurality of island patterns of the micro key overlap each other vertically.

In accordance with some embodiments of the method for manufacturing the display device of the present disclosure, a portion of the wafer exposed between neighboring ones of the plurality of island patterns is removed.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A display device comprising:
a display panel including light-emitting areas and non-light-emitting areas arranged in a row direction or a column direction;
a plurality of light-emitting elements in the light-emitting areas of the display panel and arranged in a plurality of rows and a plurality of columns; and
a plurality of micro keys in the non-light-emitting area between the light-emitting areas adjacent to each other in the row direction or the column direction.

2. The display device of claim 1, wherein each of the plurality of light-emitting elements emitting a same color of light is spaced apart from each other by a first width of 1 pixel pitch,
wherein the display device further comprises further micro keys located outside a light emitting element among the plurality of light-emitting elements at an outermost area of the display panel, each of the further micro keys spaced apart from the light emitting element by a second width greater than the first width.

3. The display device of claim 2, wherein the second width is a rational number times of the 1 pixel pitch, wherein the rational number is greater than 1.

4. The display device of claim 1, wherein the plurality of micro keys include:
a first micro key on the display panel; and
a second micro key on the display panel and spaced apart from the first micro key in the column direction of the display panel.

5. The display device of claim 1, wherein the plurality of micro keys are arranged in a same direction as a direction of travel of a laser beam used in manufacturing of the display device.

6. A method for manufacturing a display device, the method comprising:
a first transfer step of transferring a plurality of light-emitting elements, a plurality of macro keys, and a plurality of micro keys from a wafer onto a donor substrate;
providing a display panel including a plurality of light-emitting areas and a plurality of non-light-emitting areas arranged alternately with each other in a row direction or a column direction; and
a second transfer step of transferring the plurality of light-emitting elements and the plurality of micro keys from the donor substrate to the display panel,
wherein the plurality of micro keys are transferred to the non-light-emitting area between adjacent light-emitting elements among the plurality of light-emitting elements.

7. The method of claim 6, wherein the plurality of micro keys include a first micro key and a second micro key spaced apart from each other in a column direction of the display panel.

8. The method of claim 7, wherein the first transfer step includes:
a first scan in which a laser beam is irradiated to the wafer while traveling from a first scan start point at a first end of the wafer to a first scan end point at a second end opposite to the first end of the wafer in a first row of the wafer;
a second scan in which the laser beam travels from the first row in a column direction to reach a second scan start point at the second end of the wafer in a second row of the wafer and, is irradiated to the wafer while traveling from the second scan start point to a second scan end point at the first end opposite to the second end of the wafer in the second row of the wafer;
a third scan in which the laser beam travels from the second row in the column direction to reach a third scan start point at the first end of the wafer in a third row of the wafer, and is irradiated to the wafer while traveling from the third scan start point to a third scan end point at the second end opposite to the first end of the wafer in the third row of the wafer; and
a fourth scan in which the laser beam travels from the third row in the column direction to reach a fourth scan start point at the second end of the wafer in a fourth row of the wafer and is irradiated to the wafer while traveling from the fourth scan start point to a fourth scan end point at the first end opposite to the second end of the wafer in the fourth row of the wafer.

9. The method of claim 8, wherein the first micro key includes two first micro keys at the first scan start point and the first scan end point respectively,
wherein the second micro key includes two second micro keys at the third scan start point and the third scan end point respectively.

10. The method of claim 7, wherein each of the plurality of micro keys comprises an array structure that includes a plurality of island patterns arranged in a matrix manner.

11. The method of claim 10, wherein one of the plurality of island patterns has a size equal to or smaller than a size of each of the plurality of light-emitting elements.

12. The method of claim 6, wherein the plurality of light-emitting elements emitting a same color of light and arranged adjacently are spaced apart from each other by a first width equal to 1 pixel pitch,
wherein the method further comprises transferring further micro keys to an area outside a light emitting element among the plurality of light-emitting elements at an outermost area of the display panel, each of the further micro keys being spaced apart from a light-emitting element among the plurality of light-emitting elements that is closest to the further micro keys by a second width greater than the first width.

13. The method of claim 12, wherein the second width is a rational number times of the 1 pixel pitch, wherein the rational number is greater than 1.

14. The method of claim 8, wherein each of the plurality of micro keys comprises an array structure that includes a plurality of island patterns arranged in a matrix manner,
wherein the laser beam is irradiated through a laser mask to the wafer, wherein the laser mask includes a plurality of mask patterns at least partially overlapping the micro key,
wherein the laser beam travels to a center in the column direction of one of the plurality of mask patterns located at an end in the column direction of the laser mask and a center in the column direction of one of the plurality of island patterns in a first column that overlap each other vertically.

15. The method of claim 10, further comprising removing a portion of the wafer exposed between neighboring ones of the plurality of island patterns.

16. A method for manufacturing a display device, the method comprising:
providing a first donor substrate including a plurality of light-emitting elements that emit a first color of light, a second donor substrate including a plurality of light-emitting elements that emit a second color of light, and a third donor substrate including a plurality of light-emitting elements that emit a third color of light, wherein each of the first donor substrate, the second donor substrate, and the third donor substrate comprises micro keys arranged in side regions of a corresponding plurality of light-emitting elements; and
transferring the plurality of light-emitting elements and the micro keys from the first donor substrate, the second donor substrate, and the third donor substrate to each of a plurality of set areas of a display panel, such that light-emitting elements emitting different colors of light in each set area are arranged in parallel in a row direction, wherein the display panel comprises a plurality of light-emitting areas and a plurality of non-light-emitting areas arranged alternately with each other in the row direction or a column direction, and
wherein adjacent set areas in the plurality of set areas overlap with each other, and the micro keys in an overlapping region are in the non-light-emitting area between adjacent light-emitting elements among the plurality of light-emitting elements.
